(19) United States
(12) Patent Application Publication
(10) Pub. No.: US 2014/0206262 A1
(43) Pub. Date: Jul. 24, 2014

(54) POLISHING APPARATUS AND METHOD OF POLISHING SEMICONDUCTOR WAFER

(71) Applicant: Kabushiki Kaisha Toshiba, Minato-ku (JP)

(72) Inventor: Katsuyuki OONO, Mie-ken (JP)

(73) Assignee: Kabushiki Kaisha Toshiba, Minato-ku (JP)

(21) Appl. No.: 14/018,588

(22) Filed: Sep. 5, 2013

(30) Foreign Application Priority Data
Jan. 22, 2013 (JP) 2013-009494

(51) Int. Cl. B24B 9/06; H01L 21/304

(52) U.S. Cl. CPC B24B 9/065; H01L 21/304
USPC 451/44; 451/162; 451/67; 451/41

(57) ABSTRACT

An aspect of the present embodiment, there is provided a polishing apparatus, including a stage configured to be placed a semiconductor wafer thereon and to be rotated with the semiconductor wafer, a first polishing unit configured to contact a polishing tape to one portion of the semiconductor wafer on the stage, a second polishing unit configured to contact to other portion of the semiconductor wafer, the other portion being different from the one portion, a feed unit configured to feeding the polishing tape, and a recovery unit configured to recovery the polishing tape.

### CROSS REFERENCE TO RELATED APPLICATION

This application is based upon and claims the benefit of priority from prior Japanese Patent Application No. 2013-009494, filed on Jan. 22, 2013, the entire contents of which are incorporated herein by reference.

### FIELD

Exemplary embodiments described herein generally relate to a polishing apparatus and a method of polishing a semiconductor wafer.

### BACKGROUND

Polishing to remove a residual film on a periphery portion of a semiconductor wafer has generally been performed from a view point of improvement of a yield in fabricating a semiconductor device.

Furthermore, technique to polish the periphery portion of the semiconductor wafer by using a polishing tape has been demonstrated.

On the other hand, improvement of the yield has been demanded by removing the unnecessary film attached on an outer periphery portion of a back surface of the semiconductor wafer. Therefore, a polishing apparatus, which effectively polishes both the periphery portion of the semiconductor wafer and the outer periphery portion of the back surface of the semiconductor wafer, has been desired.

### BRIEF DESCRIPTION OF THE DRAWINGS

FIG. 1 is a schematically cross-sectional view showing a polishing apparatus according to a first embodiment;

FIG. 2 is a schematically conceptual view showing a twist guide according to the first embodiment;

FIG. 3 is a schematically cross-sectional view showing a polishing apparatus according to a second embodiment.

### DETAILED DESCRIPTION

An aspect of the present embodiment, there is provided a polishing apparatus, including a stage configured to be placed a semiconductor wafer thereon and to be rotated with the semiconductor wafer, a first polishing unit configured to contact a polishing tape to one portion of the semiconductor wafer on the stage, a second polishing unit configured to contact to other portion of the semiconductor wafer, the other portion being different from the one portion, a feed unit configured to feeding the polishing tape, and a recovery unit configured to recovery the polishing tape.

An aspect of another embodiment, there is provided a method of polishing a semiconductor wafer, including placing a semiconductor wafer on a stage included in a polishing apparatus, and contacting a polishing tape in the polishing apparatus on different portions of the semiconductor wafer while rotating the semiconductor wafer to polish the semiconductor wafer.

Embodiments will be described below in detail with reference to the attached drawings mentioned above. Throughout the attached drawings, similar or same reference numerals show similar, equivalent or same components, and the description is not repeated.

### First Embodiment

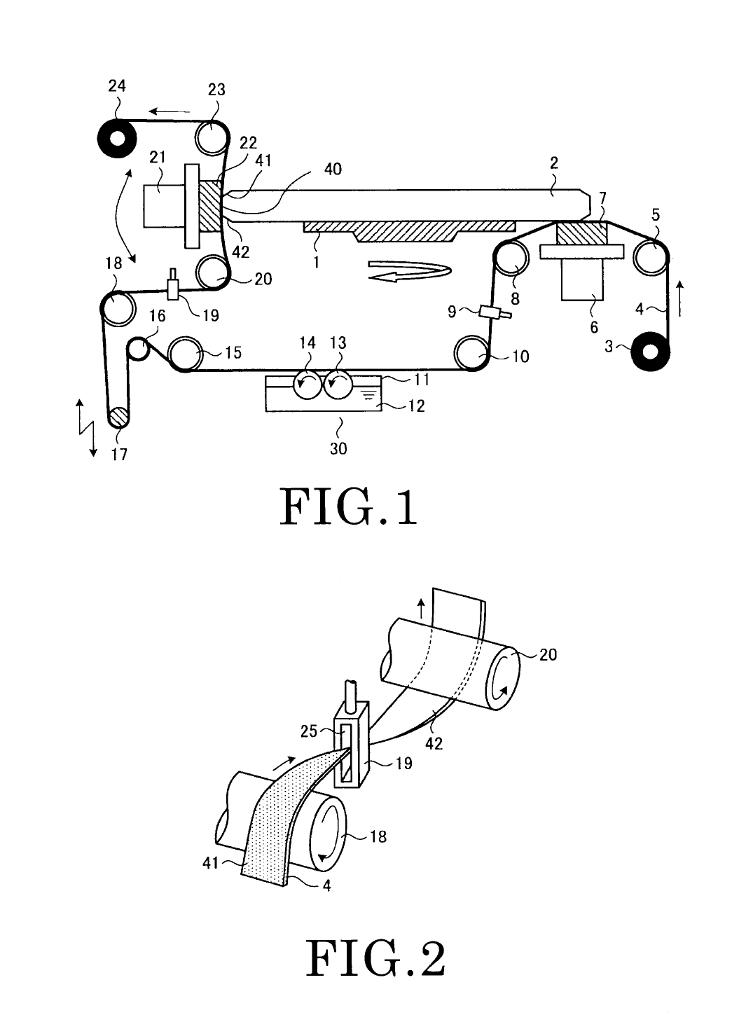

FIG. 1 is a schematic view showing a constitution of a polishing apparatus according to a first embodiment. A semiconductor wafer 2 is placed on a stage 1. The stage 1 includes a vacuum absorption unit (not shown), for example, and adsorbs the semiconductor wafer 2 in vacuum state to retain the semiconductor wafer 2. The stage 1 is provided with rotation force by a motor (not shown) to be rotated with the semiconductor wafer 2.

A first polishing unit constituted with a pressing pad 7, guide rollers 5, 8 and air cylinder 6 applied prescribed pressure to the pressing pad 7, and is placed near an outer periphery portion of a surface to be placed of the semiconductor wafer 2, where the surface to be placed, which is called a back surface, is set on the stage 1. An elastic material such as a silicone rubber, a fluorine rubber or the like, or a hard material such as a fluorine resin or the like is used as a material of the pressing pad 7. A polishing tape 4 supplied from a feed reel 3 is supplied between the pressing pad 7 and the back surface of the semiconductor wafer 2. Abrasive grains are fixed on a surface of the polishing tape 4. The feed reel 3 is driven by a prescribed motor (not shown). A polishing surface of the polishing tape 4 is in contact with the outer periphery portion of the back surface of the semiconductor wafer 2 by the pressing pad 7 with a prescribed pressure of ten newton (N), for example. The pressure applied by the pressing pad 7 is controlled by air pressure supplied to the air cylinder 6. The first polishing unit has a mechanism which is enable to transfer in a radial direction of the semiconductor wafer 2 (not shown). In such a manner, a polishing position of the outer periphery portion of the back surface of the semiconductor wafer 2 can be controlled.

The polishing tape 4 passed through the guide roller 8 is supplied to a first twist guide 9. The first twist guide 9 is provided between the first polishing unit and a cleaning unit 30, which is described after, in a path direction of the polishing tape. The polishing tape 4 is reversely rotated in the first twist guide 9 to be provided to guide roller 10 in the path direction. A constitution of the twist guide is described after.

The polishing tape 4 passed through the guide roller 10 is provided to the cleaning unit 30. The cleaning unit 30 includes a cleaning bath 11 and sponge rollers 13, 14 with two steps. A portion of the cleaning bath 11 is filled with a cleaning solution 12. The sponge rollers 13, 14 are in contact with the polishing surface of the polishing tape 4 and a lower portion of each of the sponge roller 13, 14 is dipped in the cleaning solution 12. The polishing surface of the polishing tape 4 passes on the sponge rollers 13, 14 immersed with the cleaning solution 12 to clean the polishing surface, including a contact area contacted to the semiconductor wafer 2, of the polishing tape 4. Furthermore, a drying unit which dries the polishing tape 4 with dry air (not shown) can be placed next to the cleaning unit 11. The sponge roller 13, 14 can be driven by a prescribed motor (not shown) as the constitution.

The polishing tape passed through the cleaning unit 11 is provided to a guide roller 18 through guide rollers 15, 16. A tension control weight 17 is provided between the guide rollers 16, 18. The tension control weight 17 is constituted with a weight, which is movable in an up-and-down motion and can provide the polishing tape 4 with a prescribed tension due to its own weight. In such a manner, flexure of the polishing tape 4 can be prevented.

The polishing tape 4 passed through the guide roller 18 is supplied to a second twist guide 19. The polishing tape 4 is reversely rotated again in passing through the second twist guide 19 and supplied to a guide roller 20 which constitutes a part of a second polishing unit. The second twist guide 19 is provided between the cleaning unit and the second polishing unit in the path direction of the polishing tape. The second polishing unit further includes an air cylinder 21, a pressing pad 22 and a guide roller 23. The pressing pad 22 is provided with a prescribed pressure by the air cylinder 21 so that the polishing surface of the polishing tape 4 is contacted to an end portion 40 of the semiconductor wafer 2 with a prescribed pressure of fifteen newton (N), for example. The second polishing unit further includes a tilt unit (not shown) so that an angle of the pressing pad 22 can be changed. In such a manner, the periphery portion including bevel portions 41, 42 which are formed upper and lower portions, respectively, can be polished in addition to the end portion 40 of the semiconductor wafer 2.

The polishing tape 4 passed through the guide roller 23 is rolled with a recovery reel 24 driven by a prescribed motor (not shown) to be recovered.

A polishing period can be shortened according to the first embodiment, as polishing the outer periphery portion of the back surface of the semiconductor wafer 2 by the first polishing unit and polishing the periphery portion of the semiconductor wafer 2 by the second polishing unit are simultaneously conducted. Furthermore, one polishing tape can be utilized to polish both the outer periphery portion of the back surface of the semiconductor wafer 2 and the end portion of the semiconductor wafer 2 such that the polishing tape can be cut down.

FIG. 2 shows a twist guide enlarged. The second twist guide 19 described in FIG. 1 is explained as an example. The second twist guide 19 includes a slit 25. The polishing tape 4 passed through the guide roller 18 is twisted with passing the slit 25 of the second twist guide 19 to be supplied to the guide roller 20 in a reverse state. In other words, the polishing tape 4 in which the polishing surface is set in the upper direction is reversed when the polishing tape 4 is supplied to the guide roller 18. In such a manner, the polishing tape 4 is supplied to the guide roller 20 in a state that the back surface 42 of the polishing tape 4 is set to be in the upper direction. A guide roller (not shown) can be placed in the slit 25 of the second twist guide 19 to smoothly move the twist action of the polishing tape 4. The first twist guide 9 includes the same constitution with the second twist guide 19.

### Second Embodiment

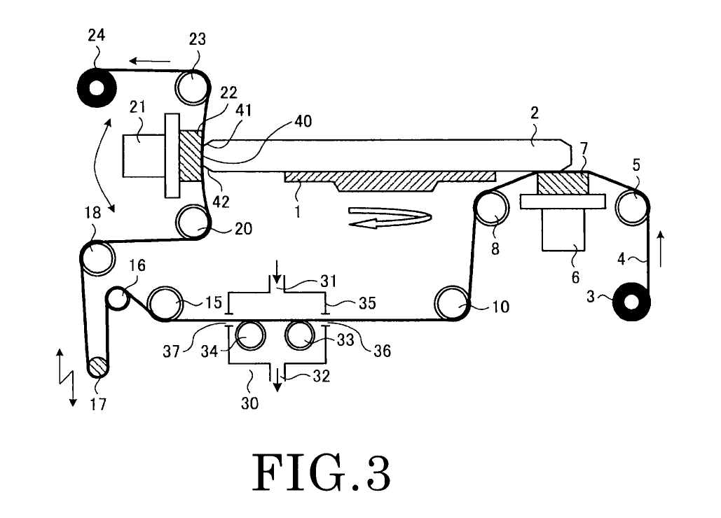

FIG. 3 is a schematically cross-sectional view showing a polishing apparatus according to a second embodiment. Throughout FIG. 3, similar or same reference numerals with FIG. 1 show similar, equivalent or same components, and the description is not repeated. A cleaning unit 30 to clean a polishing tape 4 includes a cleaning mechanism to perform a dry method in the second embodiment. In other words, the cleaning unit 30 includes a cleaning room 35 with a polishing tape inlet 36 and a polishing tape outlet 37. The cleaning room 35 further includes an intake opening 31, an exhaust opening 32 and guide rollers 33, 34 set as a two-step. The cleaning room 35 includes a constitution which can be separated up and down or opened to cover the polishing tape 4 with an upper portion and a lower portion so that a cleaning space is constituted. Dry air is supplied from the intake opening 31 so that the polishing surface of the polishing tape 4 is exposed to the dry air to clean the polishing surface, including a contact area contacted to the semiconductor wafer 2, of the polishing tape 4. The air used to clean the polishing tape 4 is exhausted from the exhaust opening 32. Evacuation from the exhaust opening 32 is sucked by a prescribed suction unit (not shown) to prevent contamination in the air from attaching to the semiconductor wafer 2 to lead to an outer portion of the polishing apparatus by a prescribed pipe (not shown).

A polishing process can be effectively conducted according to the second embodiment, as polishing the outer periphery portion of the back surface of the semiconductor wafer by the first polishing unit and polishing the periphery portion of the semiconductor wafer by the second polishing unit are simultaneously conducted. The polishing apparatus in the second embodiment is constituted to clean the polishing surface of the polishing tape 4 used to polish the outer periphery portion of the back surface of the semiconductor wafer 2 by dry air in the cleaning unit 30 supplied from the upper portion. Accordingly, a twist guide to the polishing tape is unnecessary in the second embodiment.

A constitution of initially polishing the outer periphery portion of the back surface of the semiconductor wafer 2 is explained. On the other hand, initially polishing the end portion of the semiconductor wafer 2 and secondly polishing outer periphery portion of the back surface of the semiconductor wafer 2 can be performed. Namely, rotation directions of the feed reel 3 and the recovery real 24 of the polishing tape 4 are reversed each other to lead to the above approach.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A polishing apparatus, comprising:
a stage configured to be placed a semiconductor wafer thereon and to be rotated with the semiconductor wafer;
a first polishing unit configured to contact a polishing tape to one portion of the semiconductor wafer on the stage;
a second polishing unit configured to contact to other portion of the semiconductor wafer, the other portion being different from the one portion;
a feed unit configured to feeding the polishing tape; and
a recovery unit configured to recovery the polishing tape.

2. The polishing apparatus of claim 1, further comprising:
a cleaning unit configured to clean a contact area contacted with the semiconductor wafer of the polishing tape in the first polishing unit.

3. The polishing apparatus of claim 2, wherein
the second polishing unit contacts the contact area of the polishing tape cleaned by the cleaning unit to the semiconductor wafer.

4. The polishing apparatus of claim 1, wherein
the one portion of the semiconductor wafer contacted by the polishing tape is an outer periphery portion of a surface to be placed of the semiconductor wafer, where the surface to be placed is set on the stage.

5. The polishing apparatus of claim 1, wherein
the other portion of the semiconductor wafer contacted by the polishing tape is an end portion of the semiconductor wafer.

6. The polishing apparatus of claim 2, wherein the cleaning unit includes a cleaning bath and a roller.

7. The polishing apparatus of claim 6, wherein
cleaning solution configured to be filled in a portion of the cleaning bath, a lower portion of the roller is configured to be dipped in the cleaning solution, and the contact area of the polishing tape is configured to pass on the roller immersed with the cleaning solution.

8. The polishing apparatus of claim 2, further comprising:
a drying unit configured to dry the polishing tape is arranged between the cleaning unit and the second polishing unit.

9. The polishing apparatus of claim 2, wherein
the cleaning unit includes a cleaning room having a polishing tape inlet, a polishing tape outlet, an intake opening, an exhaust opening and guide rollers.

10. The polishing apparatus of claim 2, further comprising:
a first twist guide between the first polishing unit and the cleaning unit in a path of the polishing tape, the first twist guide configured to twist the polishing tape, and
a second twist guide between the second polishing unit and the cleaning unit in the path of the polishing tape, the second twist guide configured to twist the polishing tape.

11. The polishing apparatus of claim 8, wherein
each of the first twist guide and the second twist guide includes a first guide roller, a second guide roller and a slit between the first guide roller and the second guide roller.

12. The polishing apparatus of claim 9, wherein
when the polishing tape passes through the slit, the polishing tape is twisted in the slit to be reversed in a front and back direction.

13. The polishing apparatus of claim 1, further comprising:
a tension control unit configured to provide prescribed tension to the polishing tape.

14. The polishing apparatus of claim 1, wherein
each of the first polishing unit and the second polishing unit includes a pressing pad configured to contact the to apply pressure to the polishing tape, respectively.

15. The polishing apparatus of claim 1, wherein
the first polishing unit and the second polishing unit are configured to be simultaneously driven and to simultaneously polish both the outer periphery portion of the surface to be placed and the periphery portion in the semiconductor wafer.

16. The polishing apparatus of claim 1, wherein
the second polishing unit includes a tilt unit which changes an angle of the pressing pad in the second polishing unit to the semiconductor wafer.

17. A method of polishing a semiconductor wafer, comprising:
placing a semiconductor wafer on a stage included in a polishing apparatus; and
contacting a polishing tape set in the polishing apparatus to different portions of the semiconductor wafer to polish the semiconductor wafer while rotating the semiconductor wafer.

18. The method of claim 17, wherein
the polishing tape contacts to both an outer periphery portion of a surface to be placed of the semiconductor wafer, the surface to be placed is set on the stage, and an end portion of the semiconductor wafer to simultaneously polish the outer periphery portion of the surface to be placed and the periphery portion in the polishing of the semiconductor wafer.

19. The method of claim 17, wherein
a contact area contacted to the semiconductor wafer of the polishing tape is cleaned by a cleaning unit in the polishing apparatus during polishing the outer periphery portion of the surface to be placed and the end portion in the polishing of the semiconductor wafer.

20. The method of claim 19, wherein
the contact area of the polishing tape is reversed in a front and back direction both between polishing the outer periphery portion of the surface to be placed and cleaning the contact area, and between cleaning the contact area and polishing the end portion.
